(19) United States
(12) Patent Application Publication
(10) Pub. No.: US 2012/0249909 A1
(43) Pub. Date: Oct. 4, 2012

(54) ARRAY SUBSTRATE AND LIQUID CRYSTAL DISPLAY DEVICE

(76) Inventors: Yukio TANAKA, Kanazawa-shi (JP); Kenji Nakao, Kanazawa-shi (JP)

(21) Appl. No.: 13/429,898

(22) Filed: Mar. 26, 2012

(30) Foreign Application Priority Data
Mar. 30, 2011 (JP) 2011-075507

(51) Int. Cl. G02F 1/1343; G09G 5/00; G09G 3/36; H01L 33/08

(52) U.S. Cl. 349/39; 257/88; 345/209; 257/E33.062; 345/96

(57) ABSTRACT

According to one embodiment, an array substrate includes auxiliary capacitance electrodes, auxiliary capacitance lines, signal lines, and pixel electrodes. The auxiliary capacitance electrode connected to one of the pixel electrodes adjacent to each other in a column direction and the auxiliary capacitance electrode connected to the other pixel electrode are opposed to the same auxiliary capacitance line, and extend in a row direction by intersecting the signal line.

### CROSS-REFERENCE TO RELATED APPLICATIONS

This application is based upon and claims the benefit of priority from prior Japanese Patent Application No. 2011-075507, filed Mar. 30, 2011, the entire contents of which are incorporated herein by reference.

### FIELD

Embodiments described herein relate generally to an array substrate and liquid crystal display device.

### BACKGROUND

A liquid crystal display device is generally used as an image display device. The liquid crystal display device has features that it is flat and light in weight and consumes low electric power, and hence is used as, e.g., a display of a cell phone, smart phone, PDA (Personal Digital Assistant), or personal computer. The liquid crystal display device includes an array substrate, a counter substrate arranged opposite to the array substrate, and a liquid crystal layer held between the array substrate and counter substrate. The array substrate includes a plurality of scanning lines, a plurality of signal lines, a plurality of auxiliary capacitance lines, a plurality of TFTs (Thin Film Transistors) for pixel switching, and a plurality of auxiliary capacitance elements.

Capacitively coupled driving (CC driving) has been proposed for the liquid crystal display device. In CC driving, a superposition voltage is applied to a pixel electrode via the auxiliary capacitance element by changing the potential of the auxiliary capacitance line. By using the CC driving, the amplitude (voltage value) of a video signal to be supplied to the signal line can be reduced.

Also, dot inversion driving has been proposed for the liquid crystal display device. By using this dot inversion driving, the generation of flicker can be reduced in the liquid crystal display device, particularly in a high-image-quality liquid crystal display device.

Furthermore, capacitively coupled dot inversion (CCDI) driving combining CC driving and dot inversion driving has been proposed for the liquid crystal display device.

### BRIEF DESCRIPTION OF THE DRAWINGS

FIG. 1 is a perspective view showing a liquid crystal display device according to a first embodiment;

FIG. 2 is a plan view showing the liquid crystal display device shown in FIG. 1;

FIG. 3 is an enlarged plan view showing an array substrate pixel interconnecting structure indicated by R in FIG. 2, in which four adjacent pixels are illustrated;

FIG. 4 is a sectional view showing a liquid crystal display panel taken along a line IV-IV in FIG. 3, in which auxiliary capacitance elements are illustrated;

FIG. 5 is a sectional view showing the liquid crystal display panel taken along a line V-V in FIG. 3, in which a pixel switch is illustrated;

FIG. 6 is a schematic view showing a part of the array substrate of the first embodiment, in which 2H1V-CCDI driving is explained;

FIG. 7 is a schematic view showing a part of an array substrate of a second embodiment, in which 4H1V-CCDI driving is explained;

FIG. 8 is a schematic view showing a part of an array substrate of Comparative Example 1, in which 1H1V-CCDI driving is explained;

FIG. 9 is a timing chart showing the changes in voltage levels of scanning lines and auxiliary capacitance lines shown in FIG. 8; and

FIG. 10 is an enlarged plan view showing an interconnecting structure of pixel of an array substrate of a liquid crystal display device of Comparative Example 2, in which four adjacent pixels are illustrated.

### DETAILED DESCRIPTION

In general, according to one embodiment, there is provided an array substrate comprising a plurality of auxiliary capacitance electrodes, a plurality of auxiliary capacitance lines extending in a row direction, arranged opposite to the auxiliary capacitance electrodes with a gap therebetween, and configured to form a plurality of auxiliary capacitance elements together with the auxiliary capacitance electrodes, a plurality of signal lines extending in a column direction perpendicular to the row direction, and intersecting the auxiliary capacitance lines, and a plurality of pixel electrodes electrically connected to the auxiliary capacitance electrodes. The auxiliary capacitance electrode connected to one of the pixel electrodes adjacent to each other in the column direction and the auxiliary capacitance electrode connected to the other pixel electrode are opposed to the same auxiliary capacitance line, and extend in the row direction by intersecting the signal line.

According to another embodiment, there is provided a liquid crystal display device comprising an array substrate, a counter substrate arranged opposite to the array substrate with a gap therebetween, and a liquid crystal layer held between the array substrate and the counter substrate. The array substrate comprises a plurality of auxiliary capacitance electrodes, a plurality of auxiliary capacitance lines extending in a row direction, arranged opposite to the auxiliary capacitance electrodes with a gap therebetween, and configured to form a plurality of auxiliary capacitance elements together with the auxiliary capacitance electrodes, a plurality of signal lines extending in a column direction perpendicular to the row direction, and intersecting the auxiliary capacitance lines, and a plurality of pixel electrodes electrically connected to the auxiliary capacitance electrodes. The auxiliary capacitance electrode connected to one of the pixel electrodes adjacent to each other in the column direction and the auxiliary capacitance electrode connected to the other pixel electrode are opposed to the same auxiliary capacitance line, and extend in the row direction by intersecting the signal line.

An array substrate and a liquid crystal display device including the array substrate according to a first embodiment will be explained in detail below with reference to the accompanying drawings. In this embodiment, the liquid crystal display device is a transmitting type display device, and adopts CCDI (Capacitively Coupled Dot Inversion) driving and an OCB (Optically Compensated Birefringence) mode.

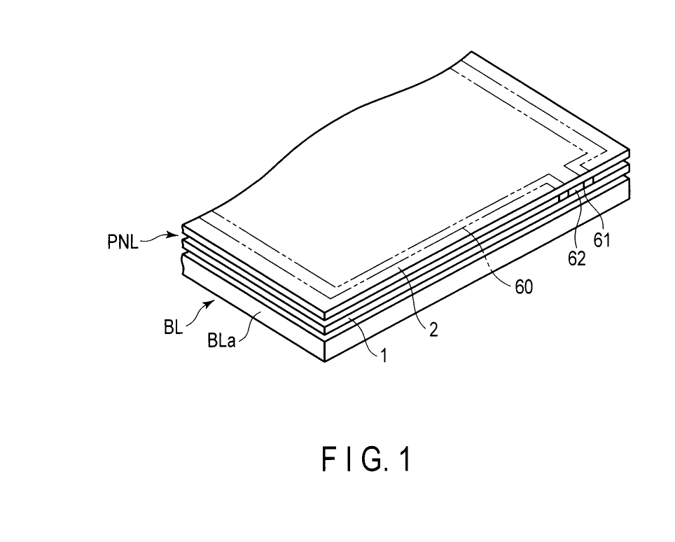

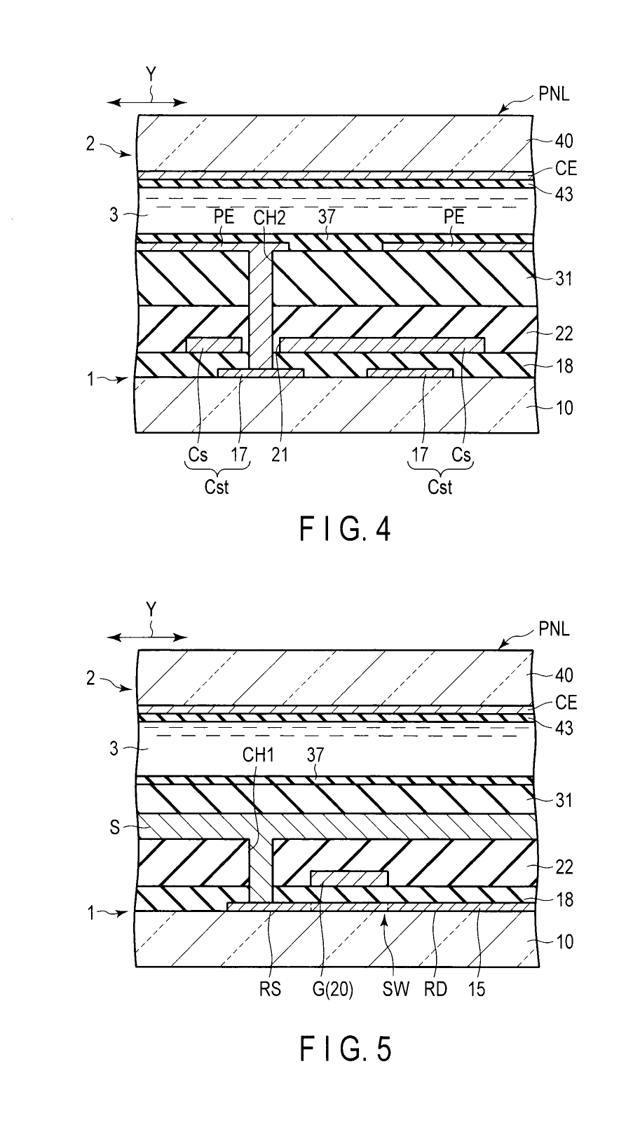

As shown in FIGS. 1, 2, 3, 4, and 5, the liquid crystal display device includes a liquid crystal display panel PNL, backlight unit BL, and control circuit CTR. The liquid crystal display panel PNL includes a pair of substrates, i.e., an array substrate 1 and counter substrate 2, and a liquid crystal layer 3. The array substrate 1 and counter substrate 2 are arranged opposite to each other with a predetermined gap therebetween. The liquid crystal layer 3 is held between the array substrate 1 and counter substrate 2.

The liquid crystal display panel PNL has a display module DYP in which the array substrate 1 and counter substrate 2 overlap each other. The display module DYP includes a plurality of pixels PX arranged in a matrix. This embodiment uses a square array as the array of the pixels PX. Also, the liquid crystal display device is a color display type device, and the pixels PX include a plurality of color display pixels. In this embodiment, the liquid crystal display device includes a pixel PXR for displaying red, a pixel PXG for displaying green, and a pixel PXB for displaying blue.

The backlight unit BL is installed to illuminate the display module DYP of the liquid crystal display panel PNL. The control circuit CTR controls the liquid crystal display panel PNL and backlight unit BL.

The array substrate 1 includes, e.g., a glass substrate 10 as a transparent insulating substrate. Outside the display module DYP, a scanning line driver GD, signal line driver SD, and auxiliary capacitance line driver CsD are provided on the glass substrate 10. The scanning line driver GD is connected to a plurality of scanning lines G extending outside the display module DYP. The scanning line driver GD sequentially drives the scanning lines G so as to turn on pixel switches SW (to be described later) row by row.

The signal line driver SD is connected to a plurality of signal lines S extending outside the display module DYP. In a period during which the pixel switches SW on each row are turned on by driving a corresponding scanning line G, the signal line driver SD outputs a video signal or non-video signal to each of the signal lines S.

The auxiliary capacitance line driver CsD is connected to a plurality of auxiliary capacitance lines Cs extending outside the display module DYP. The auxiliary capacitance line driver CsD sequentially drives the auxiliary capacitance lines Cs row by row.

The scanning line driver GD, signal line driver SD, and auxiliary capacitance line driver CsD can be formed as external ICs, or as built-in circuits on the array substrate 1 (glass substrate 10). In this embodiment, the scanning line driver GD, signal line driver SD, and auxiliary capacitance line driver CsD are arranged (as external circuits) outside the display module DYP on the array substrate 1.

In the display module DYP, the signal lines G extending in a row direction X and the signal lines S extending in a column direction Y perpendicular to the row direction are arranged on the glass substrate 10. The auxiliary capacitance lines Cs are provided on the glass substrate 10 to extend in the row direction X and parallel to the scanning lines G. The auxiliary capacitance lines Cs function as light-shielding portions. The pixel PX is formed in each region surrounded by two adjacent signal lines S and two adjacent auxiliary capacitance lines Cs.

In this embodiment, m scanning lines G (C1 to Gm), (m+1) auxiliary capacitance lines Cs (Cs1 to Csm+1), and k signal lines S (S1 to Sk) are provided on the glass substrate 10.

Next, the pixel PX will be explained.

The pixel PX includes the pixel switch SW formed as a switching element near the intersection of the signal line S and scanning line G, a pixel electrode PE electrically connected to the pixel switch SW, and an auxiliary capacitance element Cst electrically connected to the pixel electrode PE. The pixel switch SW is formed by a TFT (Thin Film Transistor).

More specifically, a plurality of semiconductor layers 15 and a plurality of auxiliary capacitance electrodes 17 are provided on the glass substrate 10. The auxiliary capacitance electrodes 17 are arranged in the row direction X, and spaced apart in the column direction Y. The semiconductor layers 15 include source regions RS, and drain regions RD connected in one-to-one correspondence with the auxiliary capacitance electrodes 17.

The semiconductor layers 15 and auxiliary capacitance electrodes 17 are simultaneously formed by using the same material by patterning a semiconductor film provided on the glass substrate 10. In this embodiment, the semiconductor layers 15 and auxiliary capacitance electrodes 17 are made of polysilicon. Also, the semiconductor layers 15 and auxiliary capacitance electrodes 17 are integrated. The semiconductor layer 15 and auxiliary capacitance electrode 17 are formed into a T-shape.

A gate insulating film 18 is deposited on the glass substrate 10, semiconductor layers 15, and auxiliary capacitance electrodes 17. The scanning lines G and the auxiliary capacitance lines Cs are formed on the gate insulating film 18.

The scanning lines G are spaced apart from the auxiliary capacitance electrodes 17 in the column direction Y. The scanning lines G intersect the semiconductor layers 15 with the gate insulating film 18 being sandwiched therebetween. The scanning lines G include a plurality of gate electrodes 20 forming the pixel switches SW together with the semiconductor layers 15.

The auxiliary capacitance lines Cs extend in the row direction X, and are spaced apart in the column direction Y. The auxiliary capacitance lines Cs oppose the auxiliary capacitance electrodes 17 with the gate insulating film 18 being sandwiched therebetween, and form the auxiliary capacitance elements Cst together with the auxiliary capacitance electrodes 17. An opening 21 is formed in each auxiliary capacitance line Cs in a region where the auxiliary capacitance line Cs overlaps the auxiliary capacitance electrode 17.

An interlayer insulating film 22 is provided on the auxiliary capacitance electrodes 17, semiconductor layers 15, scanning lines G, and auxiliary capacitance lines Cs. The interlayer insulating film 22 has a plurality of contact holes CH1 opposing the source regions RS of the semiconductor layers 15. In this embodiment, the contact holes CH1 extend through not only the interlayer insulating film 22 but also the gate insulating film 18.

The signal lines S are provided on the interlayer insulating film 22. The signal lines S extend in the column direction Y, and are spaced apart in the row direction X. The signal lines S intersect the scanning lines G and auxiliary capacitance lines Cs with the interlayer insulating film 22 being sandwiched therebetween. The signal lines S are electrically connected to the source regions RS of the semiconductor layers 15 through the contact holes CH1.

A planarizing film 31 is provided as an insulating film by using a transparent resin on the interlayer insulating film 22 and the signal lines S. In this embodiment, the planarizing film 31 is an organic insulating film. The planarizing film 31 has a plurality of contact holes CH2 overlapping the auxiliary capacitance electrodes 17 and openings 21. In this embodiment, the contact holes CH2 extend through not only the planarizing film 31 but also the interlayer insulating film 22 and gate insulating film 18.

The pixel electrodes PE are formed by a transparent conductive material such as ITO (Indium Tin Oxide) and provided on the planarizing film 31. The pixel electrodes PE are arranged in a matrix along the row direction X and column direction Y. The pixel electrodes PE are electrically connected to the auxiliary capacitance electrodes 17 through the contact holes CH2. Note that the pixel electrodes PE and auxiliary capacitance lines Cs stay insulated because the contact holes CH2 extend through the openings 21 in the auxiliary capacitance lines Cs. The pixel electrodes PE are electrically connected to the drain regions RD of the semiconductor layers 15 via the auxiliary capacitance electrode 17. The edges of each pixel electrode PE overlap two adjacent signal lines S and two adjacent auxiliary capacitance lines Cs.

The pixel electrodes PE are electrically connected in one-to-one correspondence with the auxiliary capacitance electrodes 17. The auxiliary capacitance electrode 17 connected to one of the pixel electrodes PE adjacent to each other in the row direction X in which the scanning lines G extend and the auxiliary capacitance electrode 17 connected to the other pixel electrode PE sandwich the scanning line G therebetween.

A plurality of columnar spacers (not shown) are provided on the glass substrate 10 on which the planarizing film 31, pixel electrodes PE, and the like are formed as described above. An alignment film 37 is provided on the planarizing film 31 and pixel electrodes PE on which the columnar spacers are formed.

The pixels PX each include one pixel switch SW, one auxiliary capacitance element Cst, and one pixel electrode PE. When driven via a corresponding scanning line G, each pixel switch SW electrically connects a corresponding signal line S and corresponding pixel electrode PE.

The counter substrate 2 will now be explained.

The counter substrate 2 includes, e.g., a glass substrate 40 as a transparent insulating substrate. A counterelectrode CE is provided on the glass substrate 40 by using a transparent conductive material such as ITO. The counterelectrode CE opposes the pixel electrodes PE. The control circuit CTR applies a counter voltage Vcom to the counterelectrode CE. An alignment film 43 is provided on the counterelectrode CE.

The array substrate 1 and counter substrate 2 are arranged opposite to each other with a predetermined gap being held therebetween by the columnar spacers. The array substrate 1 and counter substrate 2 are bonded by a sealing member 60 formed between the two substrates in the outer periphery of the display module DYP. The liquid crystal layer 3 is formed in a space surrounded by the array substrate 1, counter substrate 2, and sealing member 60. A liquid crystal inlet 61 is formed in a portion of the sealing member 60, and sealed by a sealant 62.

An aligning process (rubbing) is performed on the alignment films 37 and 43 in parallel directions.

Each pixel electrode PE and the counterelectrode CE form the pixel PX together with a pixel region as a part of the liquid crystal layer 3 controlled by a liquid crustal molecular alignment corresponding to electric fields from the pixel electrode PE and a counterelectrode CE.

The pixel PX has a liquid crystal capacitance formed by the liquid crystal layer 3 held between the pixel electrode PE and counterelectrode CE. The liquid crystal capacitance is determined by the relative dielectric constant of the liquid crystal material, the area of the pixel electrode PE, and the liquid crystal cell gap.

The liquid crystal display panel PNL further includes a color filter (not shown). The color filter is provided on the array substrate 1 or counter substrate 2. When providing the color filter on the array substrate 1, the color filter can be formed instead of the planarizing film 31. When providing the color filter on the counter substrate 2, the color filter can be formed between the glass substrate 40 and counter electrode CE. The color filter includes coloring layers of a plurality of colors, e.g., red, green, and blue coloring layers. The edges of each coloring layer overlap the signal lines S. The pixel

PXR includes the red coloring layer, the pixel PXG includes the green coloring layer, and the pixel PXB includes the blue coloring layer.

The backlight unit BL includes a light-guiding plate BLa, and a light source and reflecting plate (neither is shown) formed to oppose each other on one edge of the light-guiding plate BLa. The light-guiding plate BLa is arranged opposite to the array substrate 1. The liquid crystal display device also includes a bezel (not shown).

In the liquid crystal display device formed as described above, a signal (voltage) applied from the signal line driver SD to the signal lines S is applied to the pixel electrodes PE of the pixels PX on a selected row via the corresponding pixel switches SW. A potential difference between the voltage (pixel potential) applied to the pixel electrode PE and the counter voltage Vcom applied to the counter electrode CE is held in the liquid crystal capacitance. Also, the auxiliary capacitance element Cst is coupled with the liquid crystal capacitance in a holding period after the signal is written in the pixel electrode PE.

The control circuit CTR outputs a control signal to the scanning line driver GD, the control signal generated based on a sync signal input from an external signal source (not shown). In addition, the control signal CTR outputs, the control signal, and a video signal or a reverse transition preventing signal for black insertion to the signal line driver SD, the video signal and reverse transition preventing signal input from the external signal source. Furthermore, the control circuit CTR outputs the counter voltage Vcom to the counterelectrode CE of the counter substrate 2 as described above.

The signal line driver SD outputs a plurality of video signals or reverse transition preventing signals in parallel. In this embodiment, the liquid crystal display device uses CCDI driving. In CCDI driving, an amplitude increasing effect is obtained by applying a superposition voltage to the pixel potential by capacitive coupling after a signal is written in the pixel PX from the signal line S.

The liquid crystal display device is formed as described above.

Next, the auxiliary capacitance electrode 17 will be explained.

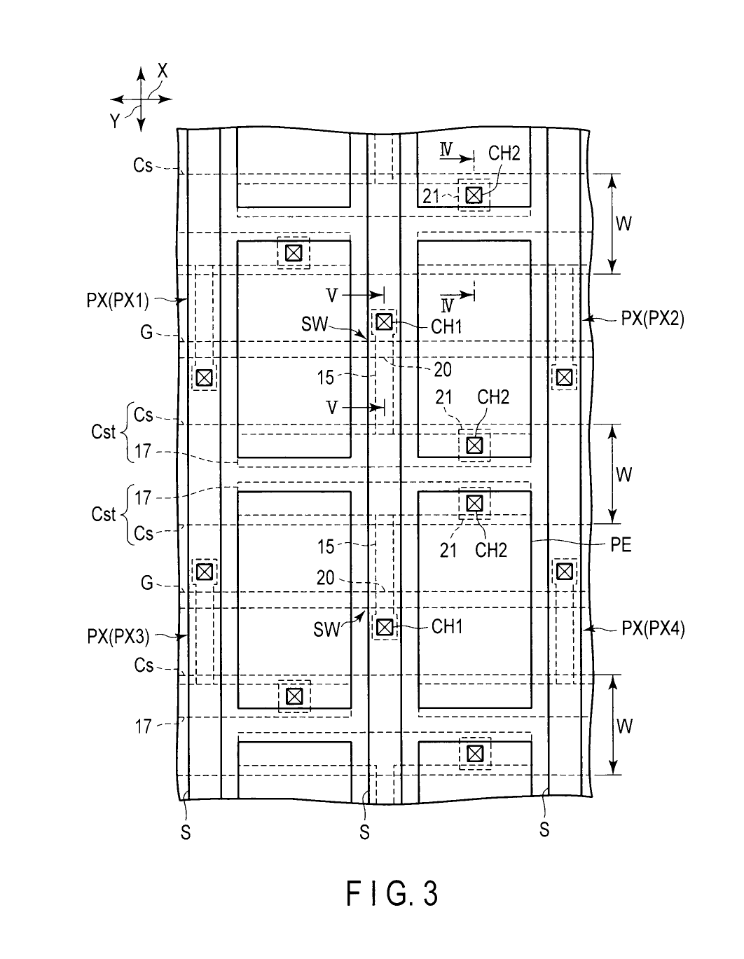

As shown in FIG. 3, the auxiliary capacitance electrode 17 connected to one of the pixel electrodes PE adjacent to each other in the column direction Y and the auxiliary capacitance electrode 17 connected to the other pixel electrode PE oppose the same auxiliary capacitance line Cs, and extend in the row direction X by intersecting the signal line S. Therefore, the auxiliary capacitance electrode 17 is formed to extend outside its own pixel region.

The signal line driver SD and auxiliary capacitance line driver CsD will be explained below.

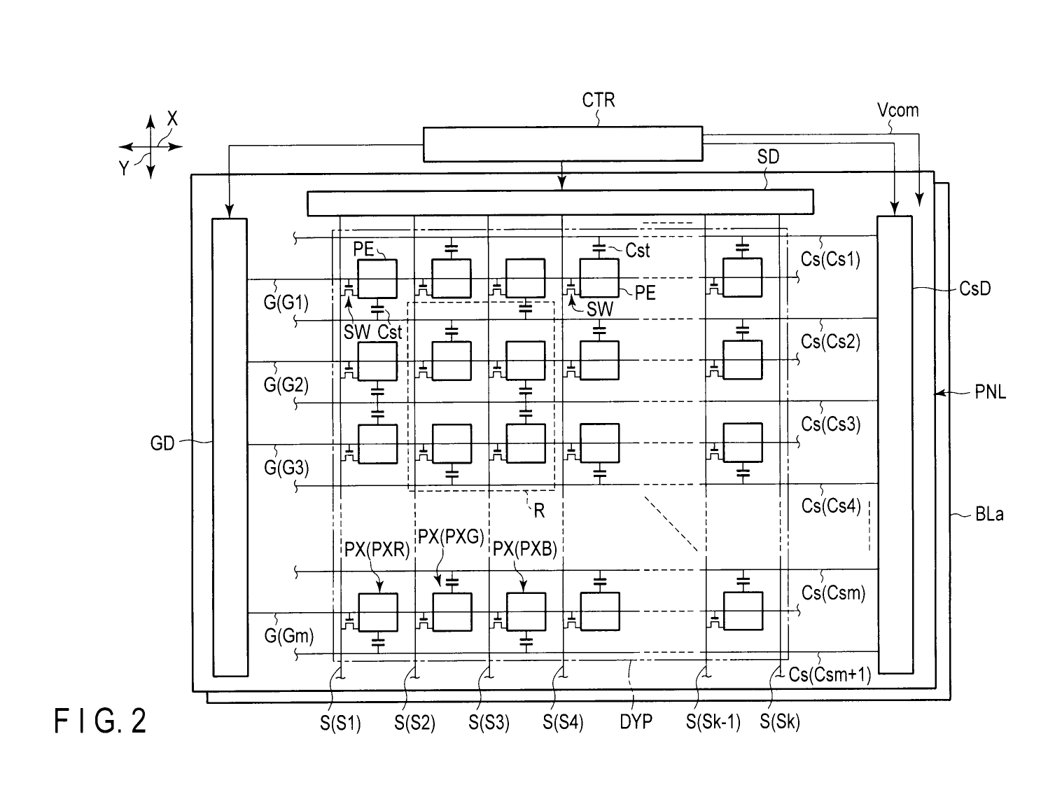

As shown in FIGS. 2 and 3, the signal line driver SD applies video signals the polarity of which is inverted every n horizontal scanning periods, to the pixel electrodes PE through the signal lines S. The auxiliary capacitance line driver CsD changes the potential of the auxiliary capacitance lines Cs, and applies the superposition voltage to the pixel electrodes PE.

n is an integer of 2 or more, and n is 2 in this embodiment.

Video signals applied from the signal line driver SD to a plurality of pixel electrodes PE connected to the same auxiliary capacitance line Cs have the same polarity.

nH1V-CCDI driving using the aforementioned liquid crystal display device will be explained below. Frist, 1H1V-CCDI driving (n=1) as the most basic driving among CCDI driving methods will be explained as Comparative Example 1. After that, 2H1V-CCDI driving (n=2) adopted by the above-mentioned liquid crystal display device will be explained.

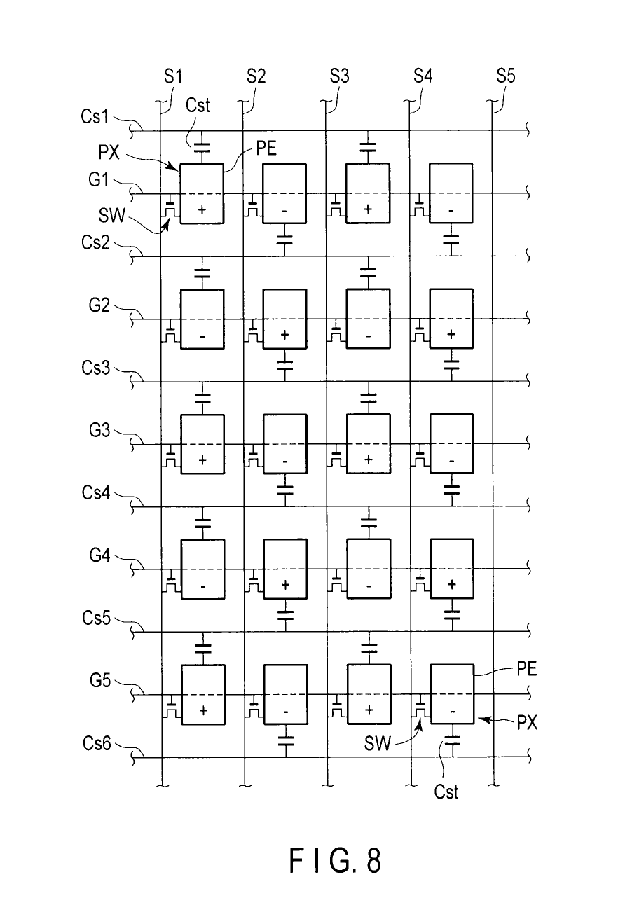

As shown in FIG. 8, 1H1V-CCDI driving is a method using so-called 1H1V inversion by which the pixels PX have their polarity inverted every other column and every other row. In this driving method, positive-polarity pixels PX and negative-polarity pixels PX are arranged like a checkers board.

The advantage of 1H1V inversion is that horizontal crosstalk can be reduced because both the positive and negative polarities exist when performing a write operation on each row, so the positive and negative polarities cancel, e.g., coupling from the signal line S to the counterelectrode CE. Also, line flicker is sometimes seen in line inversion driving or column inversion driving when the potential of the counterelectrode CE shifts. However, Comparative Example 1 using dot inversion driving has a merit that line flicker is not easily seen even when the potential of the counterelectrode CE shifts.

The auxiliary capacitance element Cst of each pixel PX is connected to the auxiliary capacitance line Cs above or below the pixel electrode PE shown in FIG. 8. More specifically, the auxiliary capacitance elements Cst of the pixels PX arranged in the row direction X are alternately connected for every other column. That is, of the auxiliary capacitance elements

Cst of the pixels PX arranged in the row direction X, the auxiliary capacitance elements Cst of the pixels PX in odd-numbered columns are connected to the auxiliary capacitance lines Cs above the pixel electrodes PE, and the auxiliary capacitance elements Cst of the pixels PX in even-numbered columns are connected to the auxiliary capacitance lines Cs below the pixel electrodes PE.

In this manner, the pixel electrodes PE connected to each auxiliary capacitance line Cs via the auxiliary capacitance elements Cst have the same polarity. For example, all the pixels PX connected to the auxiliary capacitance line Cs2 via the auxiliary capacitance elements Cst have the negative polarity, and all the pixels PX connected to the auxiliary capacitance line Cs3 via the auxiliary capacitance elements Cst have the positive polarity. This similarly applies to other auxiliary capacitance lines Cs. Generally, all the pixels PX connected to the auxiliary capacitance lines Cs on odd-numbered rows via the auxiliary capacitance elements Cst have the positive polarity, and all the pixels PX connected to the auxiliary capacitance lines Cs on even-numbered rows via the auxiliary capacitance elements Cst have the negative polarity. By thus giving the same polarity to the pixel electrodes PE connected to each auxiliary capacitance line Cs via the auxiliary capacitance elements Cst, a desired superposition voltage can be applied to each pixel PX without any conflict.

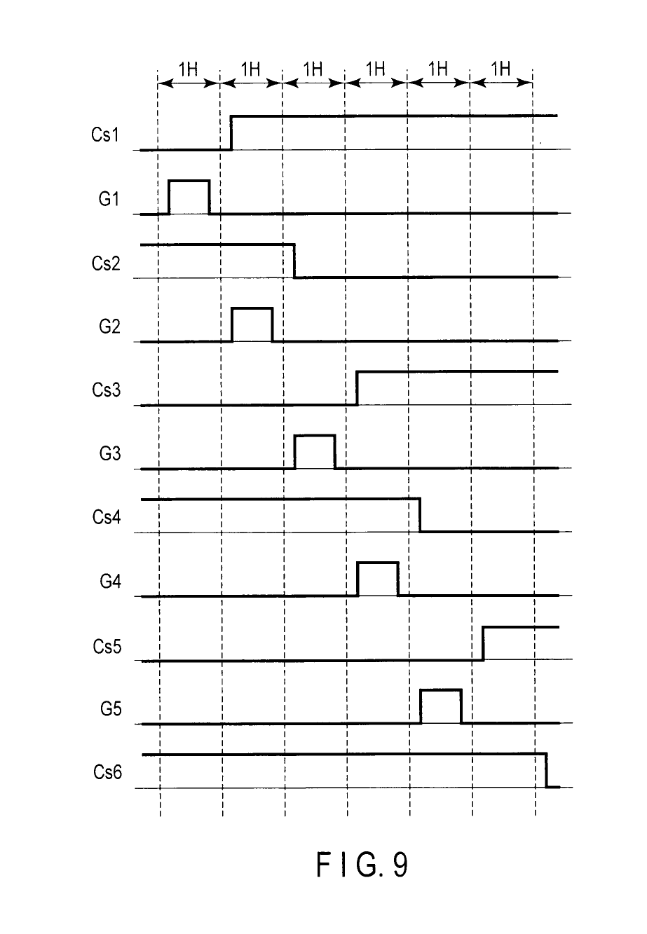

In 1H1V-CCDI driving as shown in FIGS. 8 and 9, during a period in which, e.g., the scanning line G1 is selected, the auxiliary capacitance line Cs1 connected to the auxiliary capacitance elements Cst of the pixels PX in which positive-polarity video signals are to be written, among the pixels PX on a row driven by the scanning line G1, is set in a low-voltage state (to be referred to as L hereinafter). On the other hand, the auxiliary capacitance line Cs2 connected to the auxiliary capacitance elements Cst of the pixels PX in which negative-polarity video signals are to be written, among the pixels PX on the row driven by the scanning line G1, is set in a high-voltage state (to be referred to as H hereinafter).

After the selection of the scanning line C1 is completed, the scanning line G2 is selected by changing the potential of the auxiliary capacitance line Cs1 from L to H. Consequently, a positive superposition voltage is applied, via the auxiliary capacitance elements Cst, to the pixels PX in which positive-polarity video signals are to be written, among the pixels PX on the row driven by the scanning line G1.

Then, during a period in which the scanning line G2 is selected, the auxiliary capacitance line Cs3 connected to the auxiliary capacitance elements Cst of the pixels PX in which positive-polarity video signals are to be written, among the pixels PX on a row driven by the scanning line G2, is set at L. On the other hand, the auxiliary capacitance line Cs2 connected to the auxiliary capacitance elements Cst of the pixels PX in which negative-polarity video signals are to be written, among the pixels PX on the row driven by the scanning line G2, is set at H.

After the selection of the scanning line G2 is completed, the scanning line G3 is selected by changing the potential of the auxiliary capacitance line Cs2 from H to L. Consequently, a negative superposition voltage is applied, via the auxiliary capacitance elements Cst, to the pixels PX in which negative-polarity video signals are to be written, among the pixels PX on the rows driven by the scanning lines G1 and G2.

After that, the same processing is performed when selecting the scanning lines G3, G4, . . . , Gm. Among all the pixels PX in the liquid crystal display panel PNL, a positive superposition voltage is applied, via the auxiliary capacitance elements Cst, to the pixels PX in which positive-polarity video signals are to be written, and a negative superposition voltage is applied, via the auxiliary capacitance elements Cst, to the pixels PX in which negative-polarity video signals are to be written.

Note that in the above explanation, the auxiliary capacitance line Cs2 applies the superposition voltage to both the pixels PX on the row selected by the scanning line G1 and the pixels PX on the row selected by the scanning line G2. However, no conflict occurs between them because the change in potential of the auxiliary capacitance line Cs2 after the selection is complete is H→L in either case. This similarly applies to other auxiliary capacitance lines Cs, e.g., the auxiliary capacitance lines Cs3 and Cs4; although the superposition voltage is applied to two consecutive rows, no particular conflict occurs because the change in potential of the auxiliary capacitance line Cs after the selection is completed is common to the two rows. This is so because, as explained previously, the pixel electrodes PE connected to each auxiliary capacitance line Cs via the auxiliary capacitance elements Cst have the same polarity.

As described above, it is possible to make the amplitude of the pixel holding voltage larger than the amplitude (voltage range) of a video signal to be applied from the signal line S to the pixel electrode PE, by applying the superposition voltage matching the polarity of the pixel PX to the pixel electrode PE. This makes it possible to use the signal line driver SD having a small voltage amplitude, and obtain merits that the driver cost and power consumption are reduced.

Next, 2H1V-CCDI driving adopted by the liquid crystal display device according to this embodiment will be explained below. Like 1H1V-CCDI driving, 2H1V-CCDI driving can achieve the merits that the horizontal crosstalk can be reduced, line flicker is hardly seen, the signal line driver SD having a small voltage amplitude can be used, and the driver cost and power consumption can be reduced. As will be described later, 2H1V-CCDI driving can reduce the power consumption more than that in 1H1V-CCDI driving.

As shown in FIGS. 2, 3, and 6, 2H1V-CCDI driving is the same as 1H1V-CCDI driving in that the pixels PX have their polarity inverted every other column in the column direction Y, but has a feature that the pixels PX have their polarity inverted every two rows in the row direction X. The advantage of 2H1V-CCDI driving is the ability to achieve lower power consumption than that in 1H1V-CCDI driving. That is, although the polarity of a video signal is inverted every horizontal scanning period (1H) in 1H1V inversion, the polarity of a video signal is inverted every two horizontal scanning periods (2H) in 2H1V inversion. This makes it possible to halve the frequency of signal line charge/discharge, and reduce the power consumption.

In 2H1V-CCDI driving, the layout of the auxiliary capacitance elements Cst need only be determined as follows in order to apply, to each pixel PX, the superposition voltage matching the polarity of the pixel PX. First, a “positive” or “negative” polarity is assigned to each auxiliary capacitance line Cs every other row. For example, “positive” is assigned to the auxiliary capacitance lines Cs1, Cs3, Cs5, . . . , and “negative” is assigned to the auxiliary capacitance lines Cs2, Cs4, Cs6, . . . .

For all the pixels PX, therefore, one of the upper and lower auxiliary capacitance lines Cs is “positive”, and the other is “negative”. Accordingly, the auxiliary capacitance element Cst need only be placed between each pixel PX and the auxiliary capacitance line Cs matching the polarity of a video signal to be written in the pixel PX. As a consequence, all the pixel electrodes PE connected to “positive” auxiliary capacitance lines Cs via the auxiliary capacitance elements Cst have the positive polarity, and all the pixel electrodes PE connected to “negative” auxiliary capacitance lines Cs via the auxiliary capacitance elements Cst have the negative polarity. This makes it possible to apply the superposition voltage without any conflict with the polarity of each pixel PX.

As can be seen by comparing FIGS. 6 and 8, 2H1V-CCDI driving has an outstanding feature different from the features of 1H1V-CCDI driving: some auxiliary capacitance elements Cst are arranged above the pixels PX and some are arranged below them in each column.

As shown in FIGS. 2, 3, 6, and 9, a practical procedure of 2H1V-CCDI driving is the same as that of 1H1V-CCDI driving, so a repetitive explanation thereof will be omitted.

A liquid crystal display device of Comparative Example 2 will be explained below.

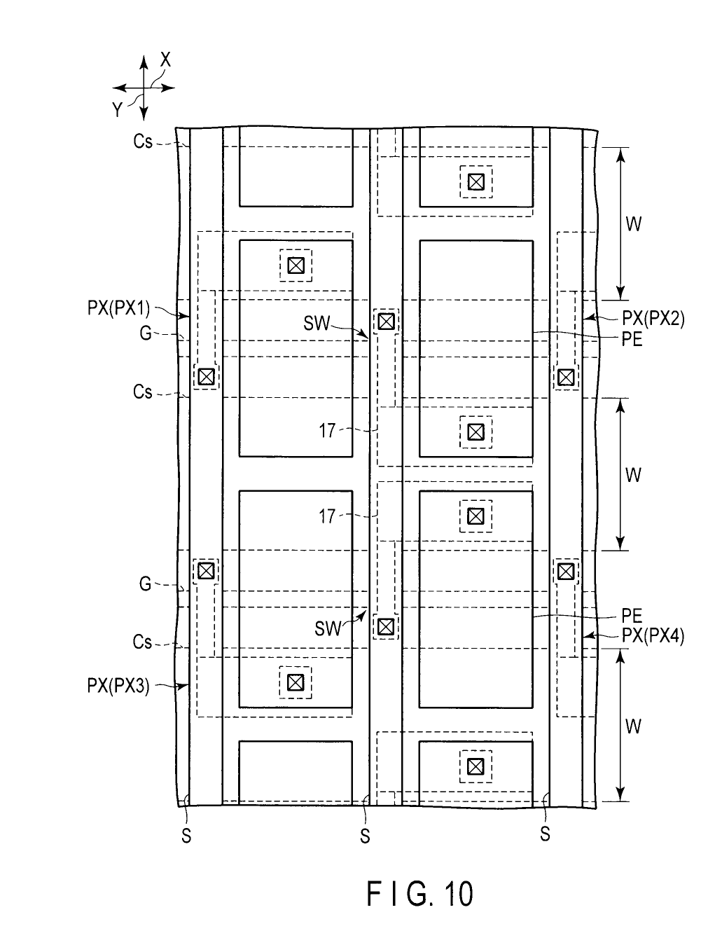

As shown in FIG. 10, the auxiliary capacitance element Cst of the pixel PX1 is formed above it, and the auxiliary capacitance element Cst of the pixel PX3 is formed below it. Therefore, the auxiliary capacitance elements Cst of the pixels PX1 and PX3 are not provided on the auxiliary capacitance line Cs between the pixels PX1 and PX3.

On the other hand, the auxiliary capacitance element Cst of the pixel PX2 is formed below it, and the auxiliary capacitance element Cst of the pixel PX4 is formed above it. Therefore, two auxiliary capacitance elements Cst must be provided on the auxiliary capacitance line Cs between the pixels PX2 and PX4 by increasing a width W of the auxiliary capacitance line Cs.

As described above, the number of auxiliary capacitance elements Cst changes from one place to another on the auxiliary capacitance line Cs. Since this produces a useless space in which no auxiliary capacitance element Cst is formed, the opening area of the pixel PX decreases (the aperture ratio decreases), and the luminance decreases. If the area of the auxiliary capacitance element Cst is decreased by decreasing the width W of the auxiliary capacitance line Cs (i.e., thinning the auxiliary capacitance line Cs) in order to prevent the decrease in aperture ratio, it becomes impossible to secure a sufficient capacity of the auxiliary capacitance element Cst, and obtain the pixel holding voltage amplitude increasing effect by capacitive coupling.

In the liquid crystal display device according to the first embodiment arranged as described above, as shown in FIG. 3, the auxiliary capacitance electrode 17 as one electrode forming the auxiliary capacitance element Cst is formed into a T-shape together with the semiconductor layer 15, and the auxiliary capacitance element Cst extends outside its own pixel region. The auxiliary capacitance element Cst according to this embodiment is formed to extend to the useless space on the auxiliary capacitance line Cs shown in FIG. 10. 2H1V-CCDI driving is driving in which the polarity of a video signal in an even-numbered column differs from that of a video signal in an odd-numbered column. As shown in FIGS. 3, 6, and 9, therefore, the auxiliary capacitance elements Cst of pixels adjacent to each other in the row direction X (horizontal direction) are always arranged in opposite positions (above and below the pixels). Accordingly, it is possible to adopt a layout in which the auxiliary capacitance elements Cst (auxiliary capacitance electrodes 17) extend outside in all the pixels PX in the display module DYP.

By using the layout as described above, it is possible to effectively use the useless space on the auxiliary capacitance line Cs, and further decrease the width W of the auxiliary capacitance line Cs. This makes it possible to secure both a large opening area (high aperture ratio) and a sufficient capacitance of the auxiliary capacitance element Cst.

Also, the signal line driver SD applies, to the signal line S, a video signal S that has its polarity inverted every two horizontal scanning periods. Accordingly, the power consumption can be reduced by more than that when a video signal that has its polarity inverted every horizontal scanning period is applied to the signal line S.

From the foregoing, it is possible to obtain a liquid crystal display device capable of suppressing the decrease in aperture ratio and reducing the power consumption.

A liquid crystal display device according to the second embodiment will be explained in detail below. In this embodiment, the arrangement is the same as that of the above-described first embodiment, so the same reference numerals denote the same parts, and a repetitive explanation thereof will be omitted.

2H1V-CCDI driving described in the first embodiment can be extended to nH1V-CCDI driving (n is an integer of 3 or more) by further increasing the polarity inversion period of a video signal. When the polarity of a video signal is inverted every n horizontal scanning periods (nH), the power consumption of charge/discharge of a signal line S can be reduced in proportion to 1/n. If n is too large, however, horizontal bands having a pitch of n rows and line flicker become conspicuous. In an actual liquid crystal display device, therefore, an optimal n value need only be selected by taking account of the required specifications of image quality and power consumption.

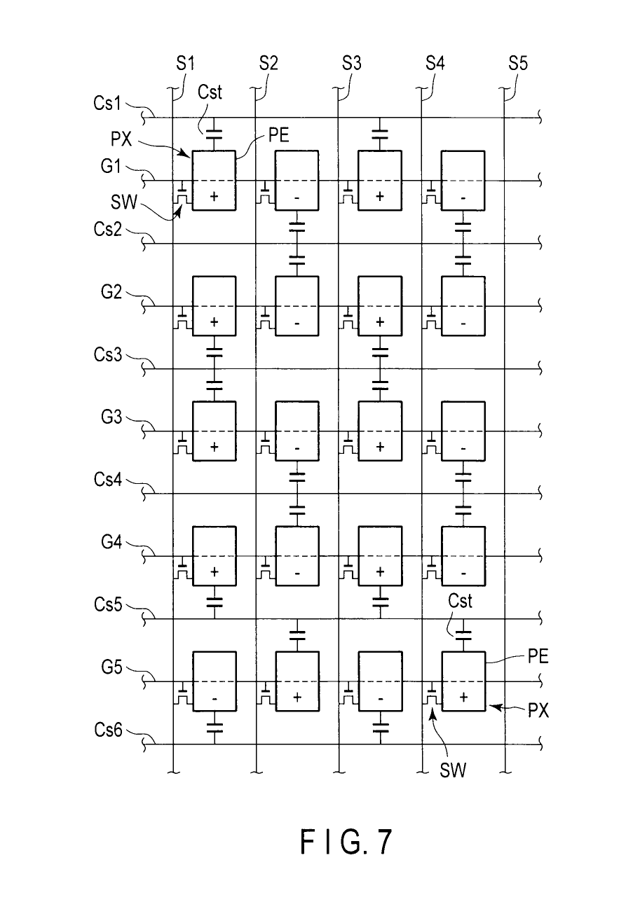

In this embodiment as shown in FIG. 7, n=4, so the liquid crystal display device uses 4H1V-CCDI driving. The layout of auxiliary capacitance elements Cst can be determined by using the same method as that for 2H1V-CCDI driving. That is, the “positive” or “negative” polarity is assigned to each auxiliary capacitance line Cs every other row. For example, “positive” is assigned to auxiliary capacitance lines Cs1, Cs3, Cs5, . . . , and “negative” is assigned to auxiliary capacitance lines Cs2, Cs4, Cs6, . . . .

For all pixels PX, therefore, one of upper and lower auxiliary capacitance lines Cs is “positive”, and the other is “negative”. Accordingly, the auxiliary capacitance element Cst need only be formed between the pixel PX and the auxiliary capacitance line Cs matching the polarity of a video signal to be written in the pixel PX. Consequently, all pixel electrodes PE connected from the “positive” auxiliary capacitance lines Cs via the auxiliary capacitance elements Cst have the positive polarity, and all pixel electrodes PE connected from the “negative” auxiliary capacitance lines Cs via the auxiliary capacitance elements Cst have the negative polarity. This makes it possible to apply a superposition voltage to each pixel PX without any conflict of polarity.

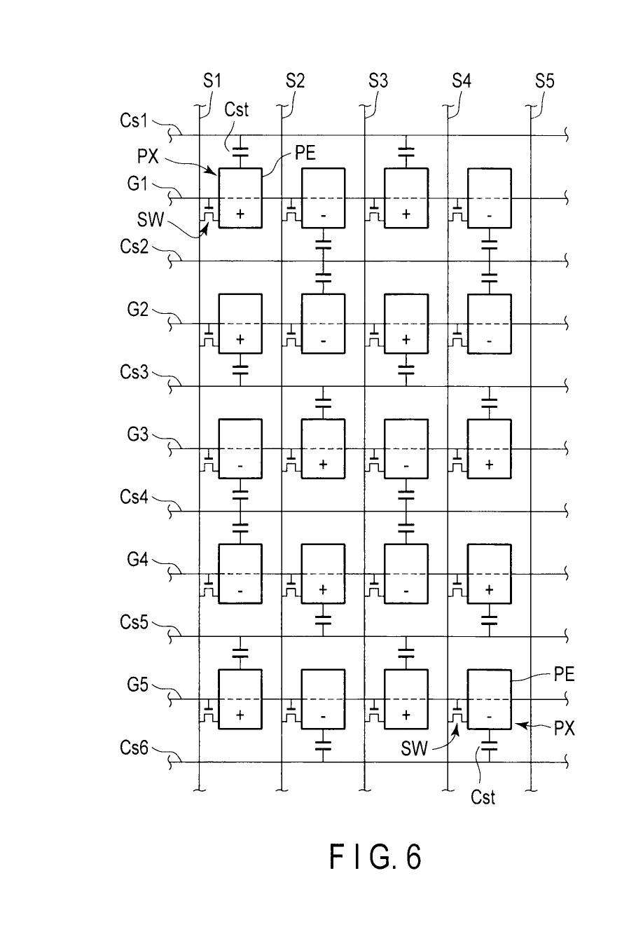

Although the pattern layout is different from that of the first embodiment (FIGS. 3 and 6), some auxiliary capacitance elements Cst are arranged above the pixels PX and some are arranged below them in each column as in the first embodiment. A practical procedure of 4H1V-CCDI driving is the same as that of 1H1V-CCDI driving or 2H1V-CCDI driving (FIG. 9), so a repetitive explanation thereof will be omitted.

In the liquid crystal display device according to the second embodiment arranged as described above, some auxiliary capacitance elements Cst are arranged above the pixels PX and some are arranged below them in each column. However, an auxiliary capacitance electrode 17 connected to one of the pixel electrodes PE adjacent to each other in a column direction Y and an auxiliary capacitance electrode 17 connected to the other pixel electrode PE oppose the same auxiliary capacitance line Cs, and extend in a row direction X by intersecting a signal line S. As in the first embodiment, therefore, it is possible to secure both a large opening area (high aperture ratio) and a sufficient capacitance of the auxiliary capacitance element Cst.

Also, the power consumption can be reduced by more than that in the first embodiment because a signal line driver SD applies, to the signal line S, a video signal that has its polarity inverted every four horizontal scanning periods.

Note that when n is maximally increased and made equal to the total number of rows in the liquid crystal display device (n=m), all pixels PX in one column have the same polarity, and this results in a CC column inversion method. Even in the CC column inversion method, a superposition voltage matching the polarity of each pixel PX can be applied to it by determining the layout of the auxiliary capacitance elements Cst by using exactly the same rules. The CC column inversion method has merits that the power consumption is low and neither horizontal bands nor line flicker occurs, but also has a demerit that vertical crosstalk readily occurs. The CC column inversion method can also be adopted by taking these merits and demerit into consideration.

From the foregoing, it is possible to obtain a liquid crystal display device capable of suppressing the decrease in aperture ratio and reducing the power consumption.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the above-described liquid crystal display device can be used in various electronic apparatuses such as a cell phone, a smart phone, and other mobile terminals. The above-described liquid crystal display device is particularly effective when applied to a liquid crystal display device required to achieve both a high-speed operation and low power consumption, such as a mobile display for displaying 3D images by time-division driving.

Furthermore, the above-described liquid crystal display device uses an OCB mode capable of high-speed response, but the present invention is not limited to this, and it is also possible to use another mode such as an IPS (In-Plane Switching) mode, TN (Twisted Nematic) mode, FFS (Fringe Field Switching) mode, or VA (Vertically Aligned) mode.

What is claimed is:

1. An array substrate comprising:
a plurality of auxiliary capacitance electrodes;
a plurality of auxiliary capacitance lines extending in a row direction, arranged opposite to the auxiliary capacitance electrodes with a gap therebetween, and configured to form a plurality of auxiliary capacitance elements together with the auxiliary capacitance electrodes;
a plurality of signal lines extending in a column direction perpendicular to the row direction, and intersecting the auxiliary capacitance lines; and
a plurality of pixel electrodes electrically connected to the auxiliary capacitance electrodes,
wherein the auxiliary capacitance electrode connected to one of the pixel electrodes adjacent to each other in the column direction and the auxiliary capacitance electrode connected to the other pixel electrode are opposed to the same auxiliary capacitance line, and extend in the row direction by intersecting the signal line.

2. The array substrate according to claim 1, further comprising:
a signal line driver connected to the signal lines, and configured to apply video signals which has a polarity inverted every n horizontal scanning periods to the pixel electrodes via the signal lines; and
an auxiliary capacitance line driver connected to the auxiliary capacitance lines, and configured to apply a superposition voltage to the pixel electrodes by changing potentials of the auxiliary capacitance lines,
wherein n is an integer of not less than 2, and
the video signals which the signal line driver applies to the pixel electrodes connected to the same auxiliary capacitance line have the same polarity.

3. A liquid crystal display device comprising:
an array substrate;
a counter substrate arranged opposite to the array substrate with a gap therebetween; and
a liquid crystal layer held between the array substrate and the counter substrate,
wherein the array substrate comprises:
a plurality of auxiliary capacitance electrodes;
a plurality of auxiliary capacitance lines extending in a row direction, arranged opposite to the auxiliary capacitance electrodes with a gap therebetween, and configured to form a plurality of auxiliary capacitance elements together with the auxiliary capacitance electrodes;
a plurality of signal lines extending in a column direction perpendicular to the row direction, and intersecting the auxiliary capacitance lines; and
a plurality of pixel electrodes electrically connected to the auxiliary capacitance electrodes, and
wherein the auxiliary capacitance electrode connected to one of the pixel electrodes adjacent to each other in the column direction and the auxiliary capacitance electrode connected to the other pixel electrode are opposed to the same auxiliary capacitance line, and extend in the row direction by intersecting the signal line.

4. The liquid crystal display device according to claim 3, which uses an OCB mode.
